(19) United States
(12) Patent Application Publication
(10) Pub. No.: US 2025/0070757 A1
(43) Pub. Date: Feb. 27, 2025

(54) FILTER STRUCTURES

(71) Applicant: FOREFRONT RF LTD, Cambridge (GB)

(72) Inventors: Leo LAUGHLIN, Cambridge (GB); Julian HILDERSLEY, Cambridge (GB); Michael GUESS, Cambridge (GB); Michael MCCULLAGH, Cambridge (GB)

(21) Appl. No.: 18/723,152

(22) PCT Filed: Dec. 22, 2022
(86) PCT No.: PCT/GB2022/053354

§ 371 Date: Jun. 21, 2024

(30) Foreign Application Priority Data
Dec. 22, 2021 (GB) GB 2118847.9

(51) Int. Cl. H03H 11/04; H04B 1/00; H04B 1/48

(52) U.S. Cl. CPC H03H 11/04; H04B 1/0057; H04B 1/48

(57) ABSTRACT

A circuit for providing self-interference cancellation in a radio transceiver, the circuit comprising: a first circuit element provided on a first substrate and comprising one or more inductors; a second circuit element provided on a second substrate and comprising one or more capacitors; at least one switching device provided on the second substrate, the switching device being capable of switching one or more of the inductors and the capacitors into or out of a signal path; and a control unit adapted to control the switching device so as to adapt the response of the signal path to perform self-interference cancellation.

This invention relates to filter structures, for example for performing filtering in radio frequency (RF) devices.

A radio frequency device such as a cellular telephone may have a single antenna for transmitting and receiving radio signals. A transmit chain is coupled to the antenna for transmitting signals from the device. A receive chain is coupled to the antenna for receiving signals from a remote device such as a base station. In modern telecommunications systems devices may be transmitting and receiving simultaneously over a wide range of frequencies. This poses considerable demands on filtering circuitry to inhibit contamination of the received signal by signals that are being transmitted and to reject other unwanted signals.

In many RF devices surface acoustic wave (SAW) and bulk acoustic wave (BAW) filters are used. These are expensive and occupy a relatively large volume. When a device is required to operate in multiple frequency bands there may be different SAW or BAW filters for different frequency bands. This increases the cost and space usage even further. One way to address this is to use tuneable filters, whose frequency response can be adjusted during operation. Tuneable filters can take various forms, for example networks of reactive components such as transformers, inductors and capacitors, with some or all of the components being adjustable or coupled via switches so that they can be selectively switched in or out of circuit as required. The latter approach calls for switches in addition to the reactive components, and a control mechanism for controlling the switches as required.

There are particular difficulties in manufacturing inductive components with high quality, e.g. with a high quality factor (Q), and small size. Known techniques for manufacturing integrated passive devices (IPDs) that are inductive is to form them by metallisation on laminates or on or through dielectric substrates such as glass.

It would be desirable to provide a filter structure, for example for an RF transceiver, that is compact and that can also have high quality passive components. It would be desirable to provide an RF transceiver which can be tuned over a range of frequencies. Such a transceiver may reduce the need for multiple SAW and/or BAW filters.

According to one aspect there is provided a circuit for providing self-interference cancellation in a radio transceiver, the circuit comprising: a first circuit element provided on a first substrate and comprising one or more inductors; a second circuit element provided on a second substrate and comprising one or more capacitors; at least one switching device provided on the second substrate, the switching device being capable of switching one or more of the inductors and the capacitors into or out of a signal path; and a control unit adapted to control the switching device so as to adapt the response of the signal path to perform self-interference cancellation.

The second circuit element may comprise the control unit. The control unit may be partially or wholly carried by or integrated in the second circuit element. This may be especially convenient if the second circuit element comprises a semiconductor substrate. The second substrate may be a semiconductor substrate. The first substrate may be of the same or a different material to the first substrate. The second substrate may, for example, be a dielectric or a semiconductor.

The first circuit element and the second circuit element may be coupled to a circuit board such that the signal path extends from a first terminal on the circuit board to a second terminal on the circuit board and the control unit is provided on the circuit board.

The control unit may be configured to compare a transmit signal with a receive signal and to control the switching device in dependence on the result of that comparison.

The first circuit element may be an integrated passives device. The first substrate may be a dielectric substrate.

The second circuit element may be a semiconductor device. The second substrate may be a semiconductor substrate.

The circuit may comprise an interconnect circuit element provided on a third substrate. The interconnect circuit element may electrically interconnect the first circuit element and the second circuit element.

The interconnect circuit element may comprise termination connectors terminating the signal path, the termination connectors being located on a first major face of the interconnect circuit element. The first circuit element may be connected on a second major face of the interconnect circuit element. The termination connectors may be connectors suitable for physically terminating an electrical connection to. They may, for example be conductive pads or solder elements, e.g. solder balls.

The second circuit element may be connected on the first major face of the interconnect circuit element.

The termination connectors may lie in a zone surrounding the second circuit element.

The circuit may comprise a data carrier storing in non-transient form code executable by the control unit to adapt the self-interference cancellation performance of the signal path.

The signal path may be coupled so as to extend between a transmit path and a receive path.

According to a second aspect there is provided a self-interference cancellation unit comprising: a first circuit element provided on a first substrate and comprising one or more inductors; a second circuit element provided on a second substrate and comprising one or more capacitors; at least one switching device provided on the second substrate, the switching device being capable of switching one or more of the inductors and the capacitors into or out of a signal path in response to a control signal received from a control unit so as to adapt the response of the signal path to perform self-interference cancellation.

According to a third aspect there is provided a radio transceiver comprising: a transmit filter coupled between a transmitter and an antenna port; a receive filter coupled between a receiver and an antenna port; and a self-interference cancellation unit as set out herein

The transmit filter may comprise: a first circuit element provided on a first substrate and comprising one or more inductors; a second circuit element provided on a second substrate and comprising one or more capacitors; at least one switching device provided on the second substrate, the switching device being capable of switching one or more of the inductors and the capacitors into or out of a signal path; and a control unit adapted to control the switching device so as to adapt the response of the signal path to perform transmit filtering.

The receive filter may comprises: a third circuit element provided on a third substrate and comprising one or more inductors; a fourth circuit element provided on a fourth substrate and comprising one or more capacitors; at least one switching device provided on the fourth substrate, the switching device being capable of switching one or more of the inductors and the capacitors into or out of a signal path; and a control unit adapted to control the switching device so as to adapt the response of the signal path to perform receive filtering.

The transmit filter and the receive filter may be coupled to the same antenna port.

The present invention will now be described by way of example with reference to the accompanying drawings. In the drawings:

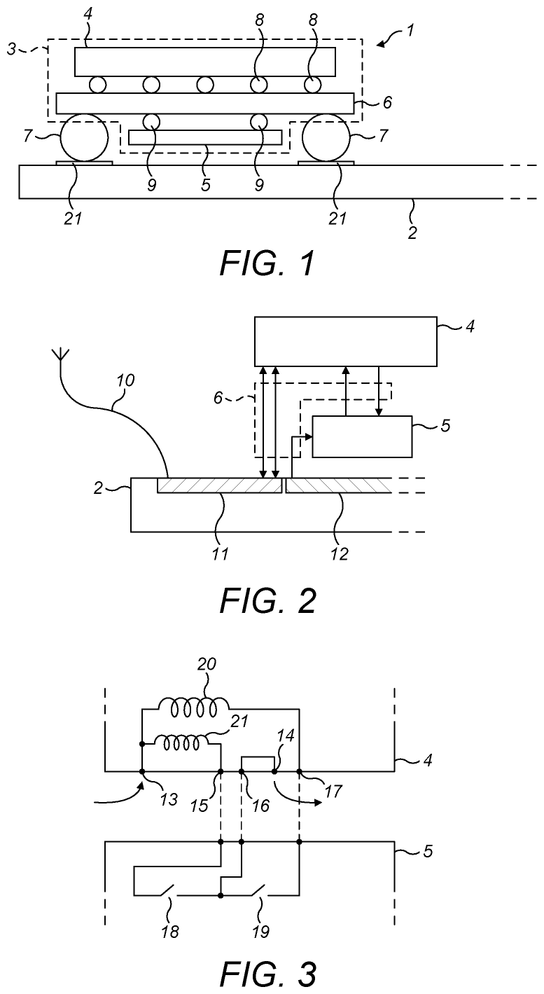

FIG. 1 is a simplified cross-section of an integrated device package.

FIG. 2 shows logical structures in the arrangement of FIG. 1.

FIG. 3 shows switching of passive components on an integrated passives unit.

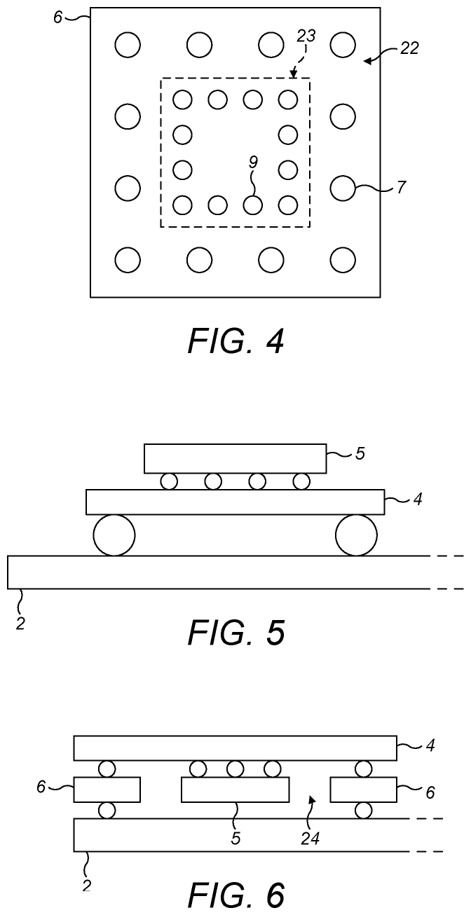

FIG. 4 shows a layout of interconnections.

FIG. 5 shows a simplified cross-section of a multi-substrate device.

FIG. 6 shows a simplified cross-section of a multi-substrate device.

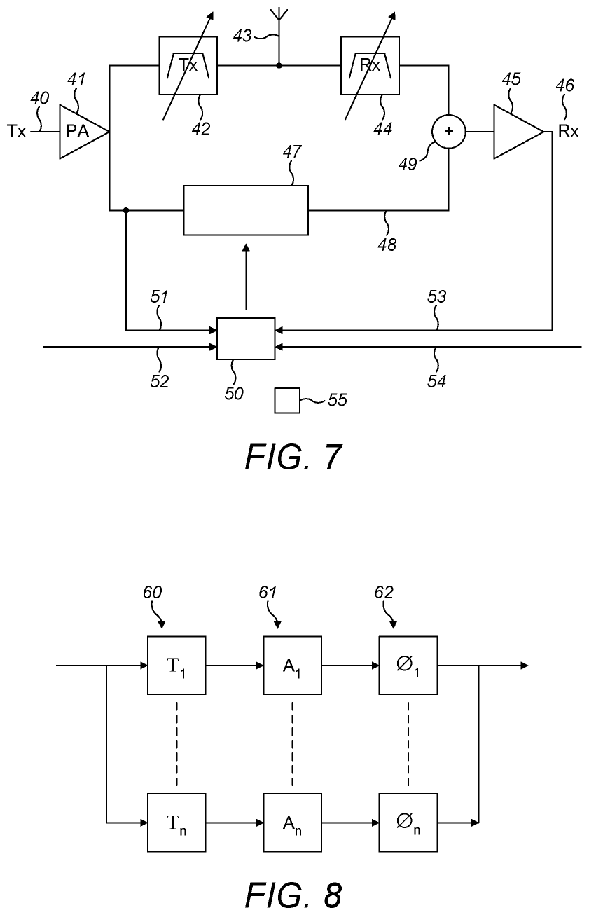

FIG. 7 shows a circuit for self-interference cancellation.

FIG. 8 shows a variable filter.

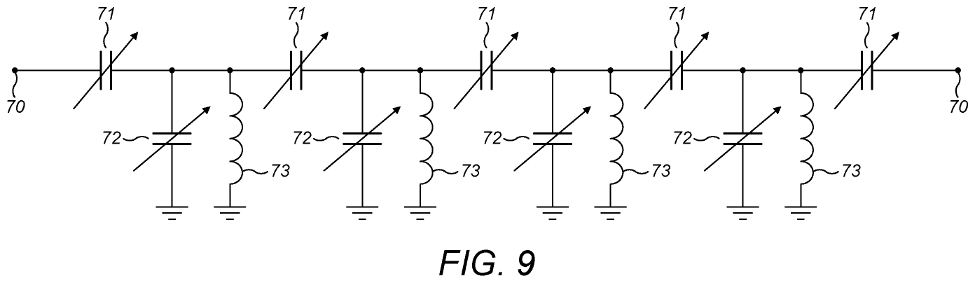

FIG. 9 shows a variable filter circuit.

FIG. 1 shows a simplified cross-section through an integrated device package 1. The integrated device package 1 is mounted on a circuit board 2. The integrated device package comprises electrical components which are encapsulated in an enclosure indicated at 3. For clarity, details of the enclosure are omitted from FIG. 1. The enclosure could be a block of epoxy or other encapsulant. Inside the enclosure are an integrated passives unit 4, an active semiconductor unit 5 and an interconnect structure 6. Solder balls 7 are provided on the outside of the package 3 for connecting between conductive pads 8 on the circuit board 2 and conductive pads (not shown) on the interconnect structure 6. Solder balls 8 connect between the interconnect structure and the integrated passives unit. Solder balls 9 connect between the interconnect structure and the active semiconductor unit 5.

The integrated passives unit 4 comprises multiple passive devices. These may include any combination of one or more of capacitors, inductors, and resistors. They may include transformers, striplines or chokes. The integrated passives unit may be formed by various technologies, examples of which are given below. In one example it may be formed by selectively depositing metallisation on, or selectively removing metallisation from, a dielectric substrate such as a polymer sheet so as to define the desired devices. Conveniently the integrated passives unit may include no switching devices. It may optionally include no semiconductor and/or semiconductor switching devices. This approach can allow the design of the integrated passives unit to be selected so as to optimise or favour the performance of the passive devices it comprises.

The active semiconductor unit 5 comprises semiconductor switching devices such as transistors. It may include a microprocessor. It may include digital circuits such as programmable registers. It may include passive components such as capacitors and/or resistors. The active semiconductor unit may be defined on or may comprise a die of a semiconductor material.

The interconnect structure 6 is an extended element which comprises conductive tracks extending between conductive pads to which solder balls 7, 8, 9 are connected. The interconnect structure bridges between the respective solder balls so that the integrated passives unit and the active unit 5 can interoperate to provide a desired capability to the circuit board 2.

FIG. 2 illustrates functionally the system of FIG. 1. An antenna 10 is coupled to an RF section 11 of circuit board 2. The integrated passives unit 4 is also coupled to the RF section 11, via the interconnect structure 6. In this way the integrated passives unit can fulfil RF functions for the circuit board 2, for example by filtering signals going between the antenna and a transmitter circuit and/or a receiver circuit on the circuit board 2. A baseband section 12 of the circuit board is coupled to the active unit 5 via the interconnect structure 6. This allows the active unit to receive commands from the circuit board 2. The active unit 5 is also coupled via the interconnect structure to the integrated passives unit. This allows the active unit to adjust the operation of the integrated passives unit. The active unit may also sense data from the integrated passives unit, for example to sense the status of the integrated passives unit. This arrangement allows, in operation, the circuit board to command the active unit to configure itself and/or the integrated passives unit in a desired way. In response, the active unit can adjust the operation of passive components it comprises and/or of the integrated passives unit, and this can alter the behaviour that the active unit and/or the integrated passives unit exhibits in the RF section 11 of the circuit board 2.

In one example, the active unit may comprise capacitors and/or resistors that can be switched into and/or out of circuit by switches of the active unit so to alter the RF behaviour that is exhibited. This may allow a resistance and/or a capacitance of the active unit to be varied in discrete steps. The active unit may comprise multiple resistive elements coupled to one or more switches so that the resistive elements collectively provide a collective resistance between two nodes that can be varied in discrete steps by operation of the switch(es). The active unit may comprise multiple capacitive elements coupled to one or more switches so that the capacitive elements collectively provide a collective capacitance between two nodes that can be varied in discrete steps by operation of the switch(es). In each case, the nodes may be presented for external connection at the exterior of the active unit. In addition, or alternatively, the active unit 5 can alter the operation of the integrated passives unit 4. One suitable option is illustrated in FIG. 3. For clarity the interconnect structure is omitted from FIG. 3. Input and output ports 13, 14 are provided on the integrated passives unit 4. They can be connected to suitable pads on the RF section 11. Inductors 20, 21 of different properties are provided on the integrated passives unit. Inductor 20 is connected between port 13 and a port 17. Inductor 21 is connected between port 13 and a port 15. Ports 15 and 17 are coupled by the interconnect layer to respective switches 18, 19 on the active unit 5. Each switch on the active unit may comprise one or more transistors. The switches can be operated to connect one or both inductors across ports 13 and 14. In that way the behaviour of the integrated passives unit can be controlled by the active unit. In the example of FIG. 3, impedance-providing components in the integrated passives unit are switched in and/or out of a circuit by means of switches located on the active unit. Each such switch on the active unit is in series with at least one such component.

The circuit extends between terminals on the integrated passives unit; in this case terminals 13 and 14. Each of those terminals is connected to the circuit board 2, conveniently via a path that includes no component that provides significant impedance in comparison to the impedance of the impedance-providing components. In this structure, control signal connections from the circuit board to the active unit pass through the interconnect unit 6. Active RF paths incorporating the passive components on the integrated passives unit 4 and communicating with the circuit board pass through the interconnect unit. Switched connections for activating components on the integrated passives unit and coupling them in such paths extend between the integrated passives unit and the active unit, passing through the interconnect unit.

Some examples of structures for the integrated passives unit 4 will now be described. The unit may be an integrated passives device (IPD). The integrated passives unit may be supported on a rigid substrate, for example of a dielectric material such as a ceramic or glass. One or more metal layers may be provided on the substrate. Where there is more than one metal layer, the layers may be spaced apart by a dielectric layer, for example a polymer layer. Inductors (which may optionally form part of a transformer) may be provided on the integrated passives unit. In one example, an inductor can be formed by one or more coils (e.g. spiral coils) in a single metal layer on the substrate. In another example, an inductor can be formed by one or more coils whose axis extends in a major plane of the substrate. This may be known as a 3D coil structure. Such a structure can, for example, be formed by connecting coil portions that are formed in two spaced-apart metal layers with electrical conductors (e.g. vias) going through a dielectric layer that separates those spaced-apart metal layers. In one example those spaced apart layers may be formed on either side of a rigid substrate, for example a glass, epoxy or high-resistance silicon substrate. In the structure illustrated in FIG. 1, the major planes of the integrated passives unit 1 and the active unit 5 are conveniently parallel to each other. This can allow for compact packaging. They are also parallel to the circuit board 2. This can allow a substantial number of connection points to the circuit board to be provided. In an arrangement of this type it can be advantageous for coil inductors comprised in the integrated passives unit to be formed such that a magnetic field generated by them is in the major plane of the integrated passives unit. That arrangement can reduce interference between the inductors and components on the active unit and/or the circuit board. One way to achieve this is for coils of the inductors to extend along a substrate of the integrated passives unit, as in the case of a 3D coil structure. When a 3D coil structure is used, two inductors may be arranged in an interpenetrating structure, with their respective vias offset from each other along the axis of the inductors, to form a transformer. In some arrangements the integrated passives unit may comprise no semiconductor components. This may provide greater freedom in the design of the integrated passives unit. Structures of the type described above may provide passive devices with high quality factors. This can help to reduce losses.

The interconnect unit 6 may be formed of one or more insulating laminates, polymer or resin sheets, carrying interconnect pads for coupling to each of the integrated passives unit 4, the circuit board 2 and the active unit 5. Conductive tracks on the insulating laminar element extend between the pads to connect the pads together in the desired way. Vias may extend through the laminar element to interconnect pads on opposite sides of the laminar element. In the example of FIG. 1, pads for connection to the integrated passives unit 4 are on one major face of the laminar element. Pads for connection to the circuit board 2 and the active unit are on the other major face of the laminar element. This arrangement can be advantageous because the active unit may typically be of smaller area than the integrated passives unit. In that situation, pads for connection to the circuit board can be provided around the periphery of pads for connection to the active unit. This arrangement is illustrated in FIG. 4. FIG. 4 shows the interconnect unit 6 from the bottom as depicted in FIG. 1. All the pads 7 for connection to the circuit board are in a zone 22. Zone 22 surrounds zone 23 which contains all the pads for connection to the active unit 5. The interconnect unit may also be known as a chip carrier.

The active unit 5 may be or comprise a semiconductor chip. It may, for example be a CMOS chip. The active unit 5 comprises switching components such as transistors. It may optionally comprise passive components that can be placed in RF circuits communicating with the circuit board 2 and incorporating inductors (which may form parts of transformers) on the integrated passives unit. Thus, in one example, the RF circuits that may be provided to the circuit board may comprise inductors, resistors and capacitors, with the inductors being provided on the integrated passives unit and some or all of the resistors and/or some or all of the capacitors being provided on the active unit.

Where resistors or capacitors are provided, whether on the integrated passives unit or the active unit, they may be provided as a bank of multiple such devices any one or more may be coupled by the active unit between a pair of terminals. Such a resistor or capacitor bank can provide a range of resistances or capacitances.

It may be advantageous for all inductors that can be switched into and out of the RF signal paths provided by the integrated passives unit and the active unit are provided on a single one of the integrated passives unit and the active unit. This can provide better control over their values and thermal stability as a result of them being subject to a common manufacturing process. It may be advantageous for all capacitors that can be switched into and out of the RF signal paths provided by the integrated passives unit and the active unit are provided on a single one of the integrated passives unit and the active unit. This can provide better control over their values and thermal stability as a result of them being subject to a common manufacturing process. It may be advantageous for all resistors that can be switched into and out of the RF signal paths provided by the integrated passives unit and the active unit are provided on a single one of the integrated passives unit and the active unit. This can provide better control over their values and thermal stability as a result of them being subject to a common manufacturing process.

It is advantageous for any inductors, capacitors and/or resistors that can be switched into and out of the RF signal paths provided by the integrated passives unit and the active unit to be arranged so that they are switched digitally, rather than under analogue control. This can provide better precision and/or stability and/or switching speed.

A switchable array of capacitors or resistors in the integrated passives unit or the active unit may comprise more than more than 6, more than 10, more than 12 or more than 16 capacitors or resistors respectively. Lower numbers of capacitors may be used.

The integrated passives unit and the active unit may be interassembled in ways other than that shown in FIG. 1. The integrated passives unit and the active unit may be connected to the same side of the interconnect unit. As illustrated in FIG. 5, the interconnect unit may be omitted and the integrated passives unit 4 may be connected directly to the circuit board with the active unit connected directly to the integrated passives unit either on the top (as shown in FIG. 5) or on the bottom. In these arrangements, control signals from the circuit board 2 to the active unit 5 pass through and are routed by conductive paths on the integrated passives unit 4. As illustrated in FIG. 6, the interconnect unit 6 may extend around the periphery of the active unit. In this arrangement the interconnect unit defines a void 24 through its major plane. The interconnect unit is connected to the circuit board 2 on one of its major faces and to the integrated passives unit 4 on the other of its major faces. The active unit is connected to the integrated passives unit on the same face of the integrated passives unit as that to which the interconnect unit is connected. The active unit is located at least partially in the void 24. In this arrangement control connections to the active unt extend through the interconnect unit and the integrated passives unit. The integrated passives unit and the active unit may be interassembled along with additional components in the same package. Examples of such additional components include (i) discrete lumped element components, (ii) semiconductor dies and (iii) IPDs.

Where connections are to be made between any two of the circuit board, the interconnect unit, the active unit and the integrated passives unit those connections may be made by any suitable conductive structure. Examples include solder balls, solder pads, metal pillars and interconnect wires. In some situations metal pillars may provide improved performance by permitting better separation of the components and thereby reducing magnetic coupling, parasitic effects and/or interference. Use of metal pillars may provide better control over the spacing between components (e.g. finer manufacturing tolerances) which may be beneficial for predicting and mitigating parasitic effects in the design.

FIG. 7 shows an example of a circuit employing an externally switched integrated passives device of the type described above. In this example, the switched integrated passives device is used to provide self-interference cancellation (partial or full cancellation). FIG. 7 shows a radio transceiver circuit. A transmit signal at 40 represents a radio frequency signal to be transmitted. A transmit signal may include signals which are desired to be transmitted in a transmit frequency band and unwanted noise and distortion in a transmit frequency band and at frequencies outside of a transmit frequency band. That signal is amplified by power amplifier 41, filtered by variable filter 42 and passed to antenna 43. On the receive side, signals received by the antenna are filtered by variable filter 44, amplified by amplifier 45 and passed to a receive terminal 46 for processing. The radio transceiver may be configured for frequency division duplex (FDD) operation, with the variable filter 42 and variable filter 44 configured to pass signals in a transmit frequency band and a receive frequency band respectively. Filter 42 and/or filter 44 may be variable filters to enable the radio transceiver circuit to vary its transmit and/or receive frequencies. Since the transmit and receive paths are connected to a common antenna it is possible for signals received by the antenna to be contaminated by interference from the signals being transmitted, e.g. after leakage through the filters, which may have imperfect stopband rejection. This can be mitigated by cancelling a representation of the transmitted signal from a signal in the receive path. For this purpose, the transmit signal (e.g. from the output of amplifier 41) can pass to a canceller 47. The canceller 47 processes the transmit signal to provide a cancellation signal at 48. The cancellation signal at 48 is formed so as to provide a degree of cancellation to the receive signal. The cancellation signal is added to the received signal at 49 so as to perform that cancellation. This can be known as self-interference cancellation. In order for the canceller 47 to form an effective self-interference cancellation signal at 48 the canceller may need to adapt very quickly to the nature of the transmit signal. The canceller 47 may be controlled by a control unit 50. The control unit 50 may select an appropriate operation of canceller 47 in response to any combination of one or more of (a) a signal 51 sensing the transmit signal, (b) a signal 52 from the transmitter's baseband indicating the nature of the transmit signal, (c) a signal 53 sensing the receive signal, from which the nature of the self-interference coupling may be estimated by control unit 50 and/or the degree of self-cancellation may be estimated by control unit 50 (e.g. by comparison with the transmit signal) and (d) a signal 54 from the receiver's baseband indicating the nature of the received signal, for example the received signal strength or an error rate of the received signal. Signals 51, 52, 53, 54 may each independently be an analogue signal or a digital signal. Each of signals 51, 52, 53, 54 may comprise or relate to one or more signals in a transmit frequency band and/or a receive frequency band. Such signals may relate to wanted signals, such as a transmit signal and/or a desired receive signal, and/or unwanted signals, which may be self-interference signals. In many applications it is desirable for the canceller 47 to be able to switch processing or filter characteristics rapidly and from multiple possible processing or filter responses. The system may select a suitable response in response to the nature of the coupling of self-interference from time to time, for example, variations in the amplitude and/or phase of the self-interference coupling channel at one or more frequencies of interest, or across a frequency band or bands of interest, which may be the transmit and/or receive frequency band. A compound device of the type described above, comprising integrated passives device 4 and active switching device 5 may be especially beneficial in this application. The active switching device may permit rapid switching between a range of responses that can be provided by the integrated passives device. In many applications it may be desirable for the canceller 47 to achieve a high degree of cancellation of transmit signals from the receive signal. This may assist the receiver in receiving incoming wireless signals whilst the transmitter is transmitting outgoing wireless signals. A compound device of the type described above, comprising integrated passives device 4 and active switching device 5 may be especially beneficial in achieving a high degree of cancellation of transmit signals from the receive signal. The active switching device 5 may permit fine control (high resolution) in the adjustment of the operation of passive components it comprises and/or of the integrated passives unit. Increased resolution may be achieved using switchable arrays of capacitors or resistors which include respective capacitors or resistors with lower respective capacitance or resistance which can be switched in or out of a circuit to provide for a smaller adjustment in a capacitance or a resistance respectively provided by the switchable array. This can provide high resolution in the control of the RF behaviour that the active unit and/or the integrated passives unit provides.

Control unit 50 may optionally control filter 42 and/or filter 44 (connection not shown in FIG. 7). Where control unit 50 is configured to control filter 42 and/or filter 44, the control unit 50 may control the switching of passive devices for the purpose of varying one of the filters 42 and 44 to select one or more frequency bands, which may be a transmit and/or receive frequency band. Control unit 50 may select a filter setting, for example a set of binary switch settings, which may be a predetermined filter setting known to configure the filter for operation in a particular frequency band.

Optionally, an antenna tuning unit (not shown in FIG. 7) may be included in the circuit between the antenna and one or more of the variable filters 42 and 44. This may be included to provide variable impedance matching between the antenna and the circuits connected to the antenna, e.g. variable filters 42 and 44. The control unit 50 may optionally control the switching of passive devices for the purpose of varying the impedance matching at the antenna port.

Control unit 50 may control active switching device 5 to switch passive components on the integrated passives device and/or on the active switching device into or out of circuit to achieve a desired response for one or more of the canceller 47, variable filter 42, variable filter 44, and/or the antenna tuning unit.

In a circuit similar to that of FIG. 7, any of a transmit filter (42 in FIG. 7) and/or a receive filter (44 in FIG. 7) and/or the canceller 47 may each be implemented using a respective integrated passives device 4 and a respective active switching device 5. A single integrated passives device and active switching device may provide more than one of the filters 42, 44 and the canceller 47.

The integrated passives device and the active switching device may be provided on a circuit board. The active switching device may be electrically coupled to the integrated passives device so that the response of a functional part of the integrated passives device can be varied in dependence on a state of the active switching device. That functional part may be provided between two terminals exposed at the exterior of the integrated passives device. In that way that part can be implemented in a circuit extending outside the combination of the integrated passives device and the active switching device. Those terminals may be electrically coupled to contacts on the circuit board. The circuit board may provide conductive paths between those contacts and further contacts by which external connection may be made to employ the functional part in an external circuit. The circuit board may electrically interconnect the integrated passives device and the active switching device. A control unit such as a processor or a combination of multiple processors may be provided to control the state of the active switching device. The control unit may be provided wholly or partly on the circuit board. The control unit may be distributed between any one or more of (i) the active switching device, (ii) the integrated passives device, and (iii) another device provided on the circuit board.

The example of FIG. 7 is a radio transceiver which may be configured for FDD (frequency division duplex) operation. However in general a compound device of the type described above, comprising integrated passives device 4 and active switching device 5, may be used in other types of radio transceivers, for example radio transceivers which simultaneously transmit and receive in a single frequency band, known as in-band full-duplex operation. Many transceiver designs are known for in-band full-duplex operation and to which the compound device described above may apply. For example, in another embodiment, the variable filter 42 and variable filter 44 may be replaced by a circulator which couples the power amplifier 41 and the receiver amplifier 45 to the antenna 42, but isolates the receiver amplifier 45 from the power amplifier 41 to some degree. In another embodiment, the power amplifier 41 and the receiver amplifier 45 may be connected to separate antennas.

FIG. 8 shows one example of a functional structure for canceller 47. This structure includes n paths in parallel between the input and the output of the canceller. Each path includes a delay element 60 for delaying a signal applied to it, an amplitude adjustment unit 61 for adjusting the amplitude of a signal applied to it, and a phase adjustment unit 62 for adjusting the phase of a signal applied to it. Two or more of these units may be integrated with each other. The units may be provided in a different order from that shown in FIG. 8. Each delay unit may apply a fixed delay or a delay commanded by control unit 50. Each amplitude adjustment unit may apply a fixed amplitude adjustment or an amplitude adjustment commanded by control unit 50. Each phase adjustment unit may apply a fixed phase adjustment or a phase adjustment commanded by phase adjustment unit 50. Any one or more of the units may be provided by a structure comprising integrated passives device 4 and active switching device 5.

FIG. 8 shows one example of a functional structure for canceller 47, however many alternative embodiments are possible. In general the advantageous arrangement comprising integrated passives device 4 and active switching device 5 may be applied in any suitable circuit used for analogue self-interference cancellation. Examples of such circuits are given in K. E. Kolodziej, B. T. Perry and J. S. Herd, “In-Band Full-Duplex Technology: Techniques and Systems Survey,” in IEEE Transactions on Microwave Theory and Techniques, vol. 67, no. 7, pp. 3025-341 July 2019, doi: 10.1109/TMTT.2019.2896561.

The canceller 47 may provide in-band cancellation. It may wholly or partially cancel from the received signal transmit signals that are in a frequency band of the signals of interest in the received signal. Alternatively or additionally, it may wholly or partially cancel from the received signal transmit signals which may be outside the frequency band of the received signal, for example it may cancel transmit signals in a transmit frequency band. Transmit signals cancelled from a receive signal may comprise desired transmit signals or undesired transmit signals such as noise and distortion or combinations thereof. The canceller 47 may provide full-duplex cancellation. It may cancel from the received signal transmit signals that are being transmitted simultaneously with signals of interest being received. The canceller 47 may cancel from the received signal transmit signals in a single contiguous frequency band, for example in an in-band full-duplex radio transceiver. The canceller 47 may cancel from the received signal transmit signals in more than one frequency band. The canceller 47 may cancel from the received signal transmit signals in a transmit frequency band and a receive frequency band, for example in a FDD radio transceiver.

Whereas the example in FIG. 7 is a radio transceiver which includes a duplexer configured to operate in a transmit frequency band and a receive frequency band, a compound device of the type described above, comprising integrated passives device 4 and active switching device 5, may be applied in a radio transceiver configured to operate in more than one transmit and/or receive frequency band, for example a radio transceiver which includes in its radio frequency circuit a multiplexer, such as a tri-plexer, quadplexer, hexaplexer, and/or an octoplexer. In a radio transceiver which includes a multiplexer in its radio frequency circuit, a plurality of self-interference cancellation circuits may be used to cancel from a plurality of received signals a plurality of transmit signals in a plurality of transmit and/or receive frequency bands.

FIG. 9 shows one example of a variable filter which may be used to implement variable filter 42 and/or filter 44. One or more instances of the example circuit in FIG. 9 may optionally be used within the canceller 47. This example provides a response between terminal nodes 70. A plurality of variable capacitor elements 71 are coupled in series between the terminal nodes 70. Nodes between respective capacitor elements are coupled to a reference voltage (in this case circuit ground) by a pairing comprising a further variable capacitor element 72 and an inductor 73 coupled in parallel. In this example the inductors are fixed and the capacitors are provided by variable capacitor banks whose response can be varied by the control unit 50. In other examples resistors and/or inductors may be switched in and out of circuit.

The control unit may be provided by dedicated hardware. The control unit may be provided by a processor. There may be a memory 55 storing in non-transient form instructions executable by the processor to perform the functions described of the control unit 50 herein. The control unit may adaptively control the canceller unit 47 to perform self-interference cancellation; that is to at least partially cancel a transmit signal from a receive signal. The control unit may adaptively control the canceller unit so as to change the response of the canceller unit to increase the degree of such cancellation. The control unit and/or the memory 55 may be provided on active unit 5 or circuit board 2 or elsewhere.

Where the apparatus described above is used as part of a radio transceiver, that transceiver may be configured to operate according to any suitable protocol. The apparatus may be especially advantageous in use with FDD or in-band full duplex transceivers.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

The phrase “configured to” or “arranged to” followed by a term defining a condition or function is used herein to indicate that the object of the phrase is in a state in which it has that condition, or is able to perform that function, without that object being modified or further configured.

1. A circuit configured to provide self-interference cancellation in a radio transceiver, the circuit comprising:
a first circuit element provided on a first substrate and comprising one or more inductors;
a second circuit element provided on a second substrate and comprising one or more capacitors;
at least one switching device provided on the second substrate, the switching device being capable of switching one or more of the inductors and the capacitors into or out of a signal path; and
a control unit adapted to control the switching device so as to adapt a response of the signal path to perform self-interference cancellation.

2. A circuit as claimed in claim 1, wherein the second circuit element comprises the control unit.

3. A circuit as claimed in claim 1, wherein the first circuit element and the second circuit element are coupled to a circuit board such that the signal path extends from a first terminal on the circuit board to a second terminal on the circuit board and the control unit is provided on the circuit board.

4. A circuit as claimed in claim 1, wherein the control unit is configured to compare a transmit signal with a receive signal and to control the switching device in dependence on a result of that comparison.

5. A circuit as claimed in claim 1, wherein the first circuit element is an integrated passives device.

6. A circuit as claimed in claim 1, wherein the first substrate is a dielectric substrate.

7. A circuit as claimed in claim 1, wherein the second circuit element is a semiconductor device.

8. A circuit as claimed in claim 1, wherein the second substrate is a semiconductor substrate.

9. A circuit as claimed in claim 1, comprising an interconnect circuit element provided on a third substrate, the interconnect circuit element electrically interconnecting the first circuit element and the second circuit element.

10. A circuit as claimed in claim 9, wherein the interconnect circuit element comprises termination connectors terminating the signal path, the termination connectors being located on a first major face of the interconnect circuit element, and the first circuit element is connected on a second major face of the interconnect circuit element.

11. A circuit as claimed in claim 10, wherein the second circuit element is connected on the first major face of the interconnect circuit element.

12. A circuit as claimed in claim 10 or 11, wherein the termination connectors lie in a zone surrounding the second circuit element.

13. A circuit as claimed in claim 1, comprising a data carrier storing in non-transient form code executable by the control unit to adapt the self-interference cancellation performance of the signal path.

14. A circuit as claimed in claim 1, wherein the signal path is coupled so as to extend between a transmit path and a receive path.

15. A self-interference cancellation unit comprising:
a first circuit element provided on a first substrate and comprising one or more inductors;
a second circuit element provided on a second substrate and comprising one or more capacitors;
at least one switching device provided on the second substrate, the switching device being capable of switching one or more of the inductors and the capacitors into or out of a signal path in response to a control signal received from a control unit so as to adapt the response of the signal path to perform self-interference cancellation.

16. A radio transceiver comprising:
a transmit filter coupled between a transmitter and an antenna port;
a receive filter coupled between a receiver and an antenna port; and
a self-interference cancellation unit as claimed in claim 15.

17. A radio transceiver as claimed in claim 16, wherein the transmit filter comprises:
a first circuit element provided on a first substrate and comprising one or more inductors;
a second circuit element provided on a second substrate and comprising one or more capacitors;
at least one switching device provided on the second substrate, the switching device being capable of switching one or more of the inductors and the capacitors into or out of a signal path; and
a control unit adapted to control the switching device so as to adapt the response of the signal path to perform transmit filtering.

18. A radio transceiver as claimed in claim 16, wherein the receive filter comprises:
a third circuit element provided on a third substrate and comprising one or more inductors;
a fourth circuit element provided on a fourth substrate and comprising one or more capacitors;
at least one switching device provided on the fourth substrate, the switching device being capable of switching one or more of the inductors and the capacitors into or out of a signal path; and
a control unit adapted to control the switching device so as to adapt the response of the signal path to perform receive filtering.

19. A radio transceiver as claimed in claim 16, wherein the transmit filter and the receive filter are coupled to a same antenna port.
